(19) United States
(12) Patent Application Publication
(10) Pub. No.: US 2007/0228365 A1
(43) Pub. Date: Oct. 4, 2007

(54) Organic anti-reflective coating polymer, organic anti-reflective coating composition comprising the coating polymer and method for forming photoresist pattern using the coating composition

(75) Inventor: Jae Chang Jung, Seoul (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC, Gyeonggi-do (KR)

(21) Appl. No.: 11/648,271

(22) Filed: Dec. 29, 2006

(30) Foreign Application Priority Data
Mar. 29, 2006 (KR) 2006-28188

(51) Int. Cl. H01L 29/08

(52) U.S. Cl. 257/40

(57) ABSTRACT

An organic anti-reflective coating polymer suitable for use in formation of a photoresist pattern acting as an ion implantation barrier during fabrication of a semiconductor device.

The organic anti-reflective coating polymer has a weight-average molecular weight of 2,000-30,000 and is represented by Formula 1 below:

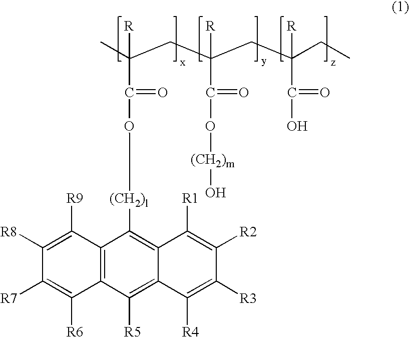

wherein R is hydrogen or methyl, R₁-R9 are each independently hydrogen, C₁-C₆ linear or branched alkyl, hydroxy, alkoxyalkyl, methoxycarbonyl, carboxyl, or hydroxymethyl, 1 is 1 or 2, m is 2, 3, or 4, and x, y, and z are each independently from 0.05 to 0.95.

### CROSS-REFERENCE TO RELATED APPLICATION

The priority Korean patent application No. 10-2006-0028188 filed Mar. 29, 2006, which is incorporated by reference in its entirety, is hereby claimed.

### BACKGROUND OF THE INVENTION

The invention relates to an organic anti-reflective coating polymer suitable for use in formation of a photoresist pattern acting as an ion implantation barrier during fabrication of a semiconductor device, an organic anti-reflective coating composition comprising the coating polymer, a method of preparing the coating polymer, and a method for forming a photoresist pattern by using the coating composition.

As semiconductor devices have become smaller in size and more highly integrated, regions necessitating selective ion implantation have become smaller. It is thus required that photoresist patterns, which act as an ion implantation barrier defining an ion implantation region, be formed in a fine-linewidth. To satisfy this requirement, deep ultraviolet (DUV) light sources and photoresists capable of making the linewidths of photoresist patterns finer, instead of i-line light sources and photoresists, are currently used in formation of the photoresist patterns acting as an ion implantation barrier.

On the other hand, when the DUV light sources and photoresists are used, a higher resolution is required. Thus, in order to prevent damage to a photoresist pattern due to diffuse reflection or standing waves from an underlayer, it is necessary to form an organic anti-reflective coating, which can sufficiently absorb the diffuse reflection or standing waves, under the photoresist pattern.

The organic anti-reflective coating must satisfy the following two characteristics.

Firstly, the organic anti-reflective coating must be not dissolved in a photoresist solvent during formation of the photoresist on the organic anti-reflective coating. Accordingly, the organic anti-reflective coating must have a crosslinking structure.

Secondly, the organic anti-reflective coating must exhibit high absorptivity at a wavelength band of an exposure light source to prevent damage to the photoresist pattern due to diffuse reflection or standing waves.

Under such circumstances, when general organic anti-reflective coatings satisfying these characteristics are formed under photoresists, and the photoresists are exposed to light, followed by developing, thereby forming photoresist patterns as an ion implantation barrier, the organic anti-reflective coatings still remain under the photoresist patterns. For this reason, to completely achieve ion implantation into an underlayer by using the photoresist patterns acting as an ion implantation barrier, there is a need for an additional process to remove the organic anti-reflective coating of an ion implantation region exposed through the photoresist patterns. In particular, since the organic anti-reflective coating has a crosslinking structure and is hardened, it is required to remove the organic anti-reflective coating of ion implantation region by additional etching. However, the method may result in complexity of process and damage to the underlayer in the ion implantation region.

### SUMMARY OF THE INVENTION

Embodiments of the invention are directed to an organic anti-reflective coating polymer, an organic anti-reflective coating composition comprising the coating polymer, a method for preparing the coating polymer, and a method for forming a photoresist pattern using the coating composition.

According to one embodiment, an organic anti-reflective coating polymer suitable for use in formation of a photoresist pattern acting as an ion implantation barrier is provided.

In one embodiment, there is provided an organic anti-reflective coating polymer having a weight-average molecular weight of 2,000-30,000, represented by Formula 1 below:

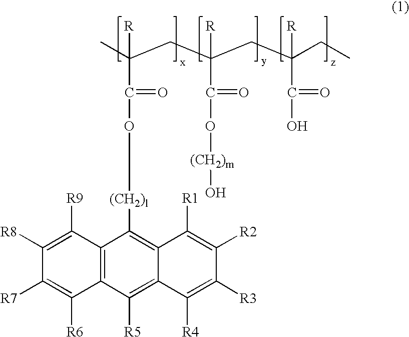

wherein R is hydrogen or methyl, R₁-R₉ are each independently hydrogen, C₁-C₆ linear, or branched alkyl, hydroxy, alkoxyalkyl, methoxycarbonyl, carboxyl, or hydroxymethyl, 1 is 1 or 2, m is 2, 3, or 4, and x, y, and z are each independently from 0.05 to 0.95.

The organic anti-reflective coating polymer preferably has a structure, wherein R is methyl, R₁-R₉ is hydrogen, 1 is 1, and m is 2 in Formula 1.

In another embodiment, there is provided a method for preparing an organic anti-reflective coating polymer of Formula 1 below:

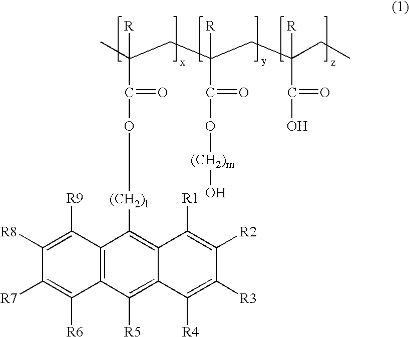

wherein R is hydrogen or methyl, R₁-R₉ are each independently hydrogen, C₁-C₆ linear, or branched alkyl, hydroxy, alkoxyalkyl, methoxycarbonyl, carboxyl, or hydroxymethyl, 1 is 1 or 2, m is 2, 3 or 4, and x, y and z are each independently from 0.05 to 0.95,

the method preferably comprising the steps of:

dissolving a 9-anthracenealkyl acrylate monomer of Formula 2 below:

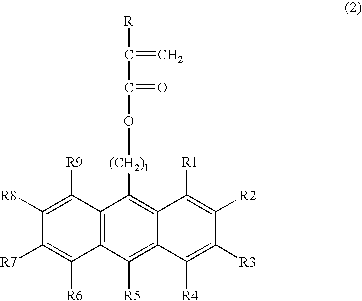

wherein R is hydrogen or methyl, R₁-R₉ are each independently hydrogen, C₁-C₆ linear, or branched alkyl, hydroxy, alkoxyalkyl, methoxycarbonyl, carboxyl, or hydroxymethyl, and 1 is 1 or 2,

a hydroxyalkyl acrylate monomer of Formula 3 below:

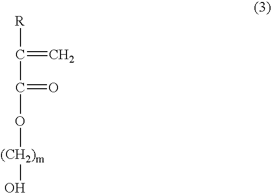

wherein R is hydrogen or methyl, and m is 2, 3, or 4, and

an acrylic acid monomer of Formula 4 below:

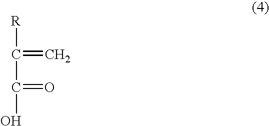

wherein R is hydrogen or methyl,

in an organic solvent; and

subjecting the mixture to copolymerization in the presence of a radical polymerization initiator at a temperature of 60° C. to 70° C. for 4 hours to 12 hours.

The organic solvent preferably includes at least one solvent selected from the group consisting of propylene glycol methyl ether acetate (PGMEA), tetrahydrofuran (THF), cyclohexanone, dimethylformamide, dimethylsulfoxide, dioxane, methyl ethyl ketone, benzene, toluene, xylene, and mixtures thereof.

The polymerization initiator preferably includes at least one initiator selected from the group consisting of 2,2-azobisisobutyronitrile (AIBN), benzoly peroxide, acetyl peroxide, lauryl peroxide, t-butyl acetate, t-butyl hydroperoxide, and di-t-butyl peroxide.
In still another embodiment, there is provided an organic anti-reflective coating composition, the composition comprising:

an organic anti-reflective coating polymer having a weight-average molecular weight of 2,000 to 30,000, represented by Formula 1 below:

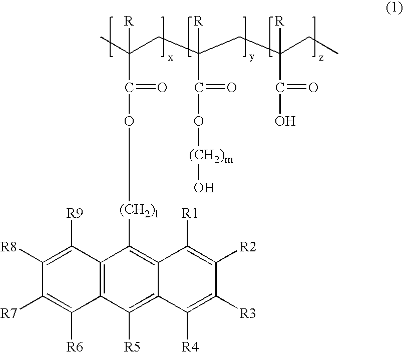

wherein R is hydrogen or methyl, R₁-R₉ are each independently hydrogen, C₁-C₆ linear or branched alkyl, hydroxy, alkoxyalkyl, methoxycarbonyl, carboxyl, or hydroxymethyl, 1 is 1 or 2, m is 2, 3, or 4, and x, y, and z are each independently from 0.05 to 0.95;

a crosslinking agent represented by Formula 5 below:

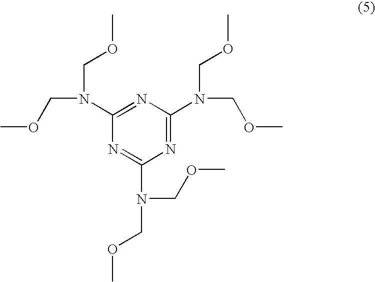

a thermal acid generator; and

an organic solvent.

The thermal acid generator preferably includes 2-hydroxycyclohexyl para-toluenesulfonate or triphenylsulfonium perfluoromethanesulfonate.

In still another embodiment, there is provided a method for forming a photoresist pattern, comprising the steps of: applying the organic anti-reflective coating composition on an ion implantation layer; baking the resulting structure to form an organic anti-reflective coating; applying a negative photoresist on the organic anti-reflective coating; and exposing the negative photoresist to light, followed by developing to form a photoresist pattern.

In the method, the baking is preferably conducted at a temperature of 150° C. to 300° C. for 1 minute to 5 minutes.

In the method, baking is preferably additionally conducted before or after exposure. At this time, the additional baking is preferably conducted at a temperature of 70° C. to 200° C.

### BRIEF DESCRIPTION OF THE DRAWINGS

FIG. 1 is a ¹H-NMR spectrum of an organic anti-reflective coating polymer prepared in Example 1; and

FIG. 2 is a scanning electron micrograph (SEM) of a photoresist pattern formed in Example 3.

### DETAILED DESCRIPTION OF THE INVENTION

In one embodiment, there is provided an organic anti-reflective coating polymer having a weight-average molecular weight of 2,000-30,000, represented by Formula 1 below:

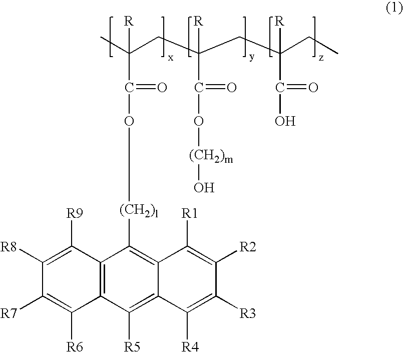

wherein R is hydrogen or methyl, R₁-R₉ are each independently hydrogen, C₁-C₆ linear, or branched alkyl, hydroxy, alkoxyalkyl, methoxycarbonyl, carboxyl, or hydroxymethyl, 1 is 1 or 2, m is 2, 3, or 4, and x, y, and z are each independently from 0.05 to 0.95.

The organic anti-reflective coating polymer preferably has a structure, wherein R is methyl, R₁-R₉ is hydrogen, 1 is 1, and m is 2 in Formula 1.

The organic anti-reflective coating polymer basically contains an anthracene group, thus exhibiting high absorptivity in response to DUV light sources (e.g., 248 nm KrF and 193 nm ArF). The organic anti-reflective coating polymer further contains a hydroxyalkyl acrylate group, thus enabling formation of a plurality of crosslinking bonds in the presence of an acid. Accordingly, when the organic anti-reflective coating polymer is used to form an organic anti-reflective coating, a plurality of crosslinking bonds are formed within the organic anti-reflective coating. As a result, it is possible to form a good organic anti-reflective coating, which is not dissolved in a photoresist solvent during formation of a photoresist.

The organic anti-reflective coating polymer further contains an acrylic acid group. Accordingly, the organic anti-reflective coating formed of the polymer can be easily removed by an alkaline developing solution. For example, when the organic anti-reflective coating is applied together with a negative photoresist (wherein the photoresist in an unexposed region is removed, thereby forming a photoresist pattern), the organic anti-reflective coating in an unexposed region maintains its original characteristics due to the acrylic acid group, thus being removed together with the negative photoresist by the alkaline developing solution.

On the other hand, in an exposed region, thermal energy emitted from an exposure light source is transmitted to a portion of the organic anti-reflective coating, thereby causing an increase in crosslinking bonds within the organic anti-reflective coating. Thus, the negative photoresist and organic anti-reflective coating in the exposed region still remain.

As a result, a photoresist pattern acting as an ion implantation barrier, in which the organic anti-reflective coating in an ion implantation region defined by the unexposed region is removed, can be formed without any additional etching. An underlayer can be subjected to ion implantation through the photoresist pattern. In addition, since the organic anti-reflective coating is removed by the developing solution in the unexposed region, rather than the exposed region, no organic anti-reflective coating remains on the underlayer in the ion implantation region (i.e., the unexposed region) after exposure to light.

As described above, the organic anti-reflective coating polymer is preferably applied to form the organic anti-reflective coating in the process of forming the photoresist pattern as an ion implantation barrier.
The organic anti-reflective coating polymer has a weight-average molecular weight of 2,000-30,000. When the organic anti-reflective coating polymer has a weight-average molecular weight smaller than 2,000, an organic anti-reflective coating may be dissolved in a photoresist solution, thus resulting in a deterioration in film-formability of the coating. Also, the organic anti-reflective coating does not exhibit sufficiently high absorptivity in response to an exposure light source, making it nearly impossible to show its antireflection functions under the photoresist pattern. Meanwhile, when the organic anti-reflective coating polymer has a weight-average molecular weight larger than 30,000, the organic anti-reflective coating may not be completely dissolved and removed by the alkaline developing solution. As a result, the organic anti-reflective coating may remain on the underlayer in the ion implantation region defined by the unexposed region.
The organic anti-reflective coating polymer of Formula 1 can be prepared by dissolving a 9-anthracenealkyl acrylate monomer of Formula 2 below:

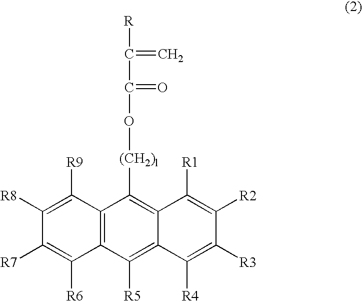

wherein R is hydrogen or methyl, R₁-R₉ are each independently hydrogen, C₁-C₆ linear or branched alkyl, hydroxy, alkoxyalkyl, methoxycarbonyl, carboxyl, or hydroxymethyl, and 1 is 1 or 2,

a hydroxyalkyl acrylate monomer of Formula 3 below:

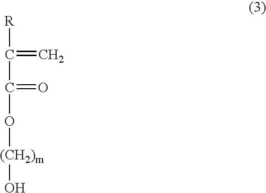

wherein R is hydrogen or methyl, and m is 2, 3, or 4, and

an acrylic acid monomer of Formula 4 below:

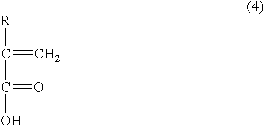

wherein R is hydrogen or methyl, in an organic solvent; and

subjecting the mixture to copolymerization in the presence of a radical polymerization initiator.

For example, the 9-anthracenealkyl acrylate monomer of Formula 2, the hydroxyalkyl acrylate monomer of Formula 3 and the acrylic acid monomer of Formula 4 are dissolved in an organic solvent, and then a radical polymerization initiator is added to the solution. Subsequently, the mixture is subjected to copolymerization at a temperature of 60° C. to 70° C. for 4 hours to 8 hours, thereby giving the final polymer of Formula 1.

As the organic solvent used to prepare the organic anti-reflective coating polymer, there is preferably used at least one solvent selected from the group consisting of propylene glycol methyl ether acetate (PGMEA), tetrahydrofuran (THF), cyclohexanone, dimethylformamide, dimethylsulfoxide, dioxane, methyl ethyl ketone, benzene, toluene, xylene, and mixtures thereof. However, the organic solvent used to prepare the organic anti-reflective coating polymer is not limited thereto, so long as it may be any organic solvent suitable for use in free radical copolymerization reactions.

The radical polymerization initiators may be any radical polymerization initiator suitable for use in free radical polymerization reactions, for example, 2,2-azobisisobutyronitrile (AIBN), benzoly peroxide, acetyl peroxide, lauryl peroxide, t-butyl acetate, t-butyl hydroperoxide, or di-t-butyl peroxide.
In another embodiment, there is provided an organic anti-reflective coating composition, the composition comprising:

an organic anti-reflective coating polymer having a weight-average molecular weight of 2,000 to 30,000, represented by Formula 1 below:

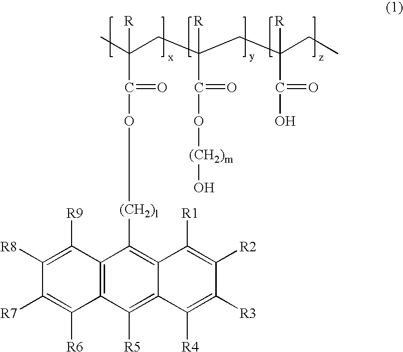

wherein R is hydrogen or methyl, R₁-R₉ are each independently hydrogen, C₁-C₆ linear or branched alkyl, hydroxy, alkoxyalkyl, methoxycarbonyl, carboxyl, or hydroxymethyl, 1 is 1 or 2, m is 2, 3, or 4, and x, y, and z are each independently from 0.05 to 0.95;

a crosslinking agent represented by Formula 5 below:

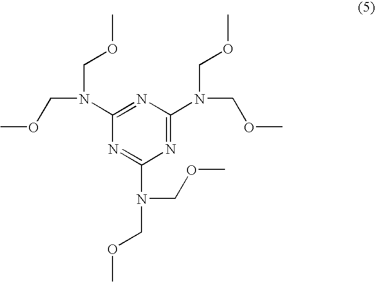

a thermal acid generator; and

an organic solvent.

The organic anti-reflective coating composition comprises the organic anti-reflective coating polymer of Formula 1 basically containing an anthracene group. Accordingly, when the organic anti-reflective coating composition is used to form an organic anti-reflective coating under a photoresist, desired high absorptivity of the organic anti-reflective coating is maintained in response to DUV light sources (e.g., 248 nm KrF and 193 nm ArF), thereby effectively preventing damage to a photoresist pattern due to diffuse reflections or standing waves, etc. from an underlayer.

The organic anti-reflective coating composition comprises the crosslinking agent of Formula 5 and thermal acid generator as well as the organic anti-reflective coating polymer of Formula 1 containing a hydroxyalkyl acrylate group. Accordingly, when the composition is applied, followed by thermal processing, an acid is generated from the thermal acid generator. An interaction between the organic anti-reflective coating polymer of Formula 1 and the crosslinking agent of Formula 5 induces a plurality of crosslinking bonds in the presence of the acid, thus enabling formation of a good organic anti-reflective coating that is not dissolved in a photoresist solvent.
The organic anti-reflective coating polymer of Formula 1 contained in the organic anti-reflective coating composition further contains an acrylic acid group. Accordingly, the organic anti-reflective coating formed of the composition can be easily removed itself by an alkaline developing solution. For example, when the organic anti-reflective coating is applied together with a negative photoresist, in an unexposed region, it is removed along with the negative photoresist by an alkaline developing solution. On the other hand, in an exposed region, crosslinking bonds increase within the organic anti-reflective coating. Thus, the negative photoresist and organic anti-reflective coating in the exposed region still remain. As a result, the photoresist pattern acting as an ion implantation barrier, in which the organic anti-reflective coating in an ion implantation region defined by the unexposed region is removed, can be formed even without any additional etching to remove the organic anti-reflective coating. An underlayer can be subjected to ion implantation through the photoresist pattern. In addition, since the organic anti-reflective coating is removed by the developing solution in the unexposed region, rather than the exposed region, no organic anti-reflective coating remains on the underlayer in the ion implantation region (i.e., the unexposed region) after exposure to light.

As described above, the organic anti-reflective coating composition is preferably applied to form the organic anti-reflective coating in the process of forming the photoresist pattern as an ion implantation barrier.
On the other hand, the thermal acid generator used in the organic anti-reflective coating composition may be any suitable material. For example, as the thermal acid generator, 2-hydroxycyclohexyl para-toluenesulfonate or triphenylsulfonium perfluoromethanesulfonate may be used.

The thermal acid generator is a catalyst for activating crosslinking reactions based on the interaction between the organic anti-reflective coating polymer of Formula 1 and the crosslinking agent of Formula 5. When the organic anti-reflective coating composition is applied, followed by thermal processing, an acid is generated from the thermal acid generator. The crosslinking reaction is activated in the presence of the acid generated from the thermal acid generator to form an organic anti-reflective coating that is not dissolved in a photoresist solvent.

Examples of suitable organic solvents that can be used in the organic anti-reflective coating composition include any suitable organic solvent. For example, as the organic solvent, ethyl 3-ethoxypropionate, methyl 3-methoxypropionate, cyclohexanone, or propylene glycol methyl ether acetate (PGMEA) may be used.

In still another embodiment, there is provided a method for forming a photoresist pattern, comprising the steps of applying the organic anti-reflective coating composition on an ion implantation layer, baking the resulting structure to form an organic anti-reflective coating; applying a negative photoresist on the organic anti-reflective coating, and exposing the negative photoresist to light, followed by developing to form a photoresist pattern.

According to the method in which the organic anti-reflective coating composition of another embodiment is used, a photoresist in an ion implantation region defined as the unexposed region (e.g., a negative photoresist) can be removed together with the organic anti-reflective coating after light-exposing and developing, even without any additional etching. Accordingly, the organic anti-reflective coating of ion implantation region does not remain on the underlayer, thereby avoiding non-uniform ion implantation and undesired device characteristics resulting from organic anti-reflective coating residues.

In the method for forming a photoresist pattern, the baking is preferably conducted at 150° C.-300° C. for 1 minute to 5 minutes. When the baking is conducted under the above conditions, an acid is generated from the thermal acid generator, and a plurality of crosslinking bonds are formed to form an organic anti-reflective coating that is not dissolved in a photoresist solvent.

In the method, baking is preferably additionally conducted, either before or after exposure. At this time, the additional baking may be conducted at a temperature of 70° C. to 200° C.

The anti-reflective coating composition and the photoresist pattern formation method are mainly applied to processes for forming photoresist patterns using a KrF light source (248 nm). Likewise, the composition and the method can be applied to processes for forming photoresist patterns using a light source, such as ArF, EUV, E-beam, X-rays or ion beam.

### EXAMPLES

The embodiments are described in more detail below, with reference to the following examples. However, these examples are given for the purpose of illustration and are not to be construed as limiting the scope of the invention.

### Example 1

### Preparation of Organic Anti-Reflective Coating Polymer

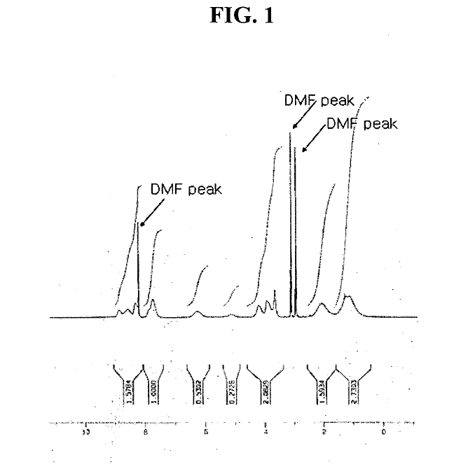

54 g of 9-anthracenemethyl methacrylate, 32 g of 2-hydroxyethyl methacrylate, 14 g of methacrylate, 3 g of AIBN and 600 g of cyclohexanone were put in a round-flask. The mixture was polymerized under nitrogen atmosphere at a temperature of 67° C. for 8 hours. After completion of the polymerization, the polymerization product was precipitated in ethyl ether, and dried in vacuo to obtain a poly(9-anthracenemethyl methacrylate-2-hydroxyethyl methacrylate-methacrylic acid) copolymer (yield: 87%). The structure of the copolymer was identified by ¹H-NMR spectroscopy (FIG. 1).

### Example 2

### Preparation of Organic Anti-Reflective Coating Composition

10 g of the copolymer prepared in Example 1, 0.5 g of triphenylsulfonium perfluoromethanesulfonate and 1.0 g of 2,4,6-tris(dimethoxymethylamino)-1,3,5-triazine as a crosslinking agent of Formula 5, and 0.2 g of 2-hydroxycyclohexyl para-toluenesulfonate as a thermal acid generator were dissolved in 250 g of cyclohexanone, and filtered through a microfilter (0.05 μm) to prepare an organic anti-reflective coating composition.

### Example 3

### Formation of Photoresist Pattern

The organic anti-reflective coating composition prepared in Example 2 was applied to a thickness of about 60 nm on a silicon wafer, and baked at 190° C. for about one minute to form an organic anti-reflective coating.

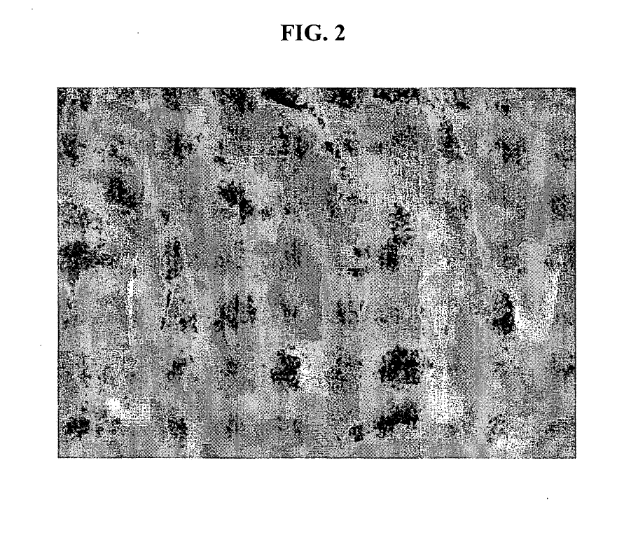

A KrF negative photoresist (Dongjin Semichem Co., Ltd. (South Korea)) was coated on the organic anti-reflective coating, and baked at 100° C. for 90 seconds, thereby forming a negative photoresist having a thickness of 340 nm. Thereafter, the resulting structure was exposed to light using KrF exposure equipment, baked at 100° C. for 90 seconds, and developed with a 2.38 wt % TMAH developing solution for 40 seconds to form a final photoresist pattern. An image of the photoresist pattern is shown in FIG. 2.

As can be seen from the results of Example 3 and the image shown in FIG. 2, the organic anti-reflective coating formed in accordance with Examples is removed together with the negative photoresist in an unexposed region during developing, but still remains in an exposed region. Accordingly, even without any additional etching, it is possible to form a photoresist pattern as an ion implantation barrier, in which the organic anti-reflective coating of an ion implantation region defined as the unexposed region is removed. In particular, no organic anti-reflective coating remains on the underlayer of ion implantation region (i.e., the unexposed region)

What is claimed is:

1. An organic anti-reflective coating polymer having a weight-average molecular weight of 2,000-30,000, represented by Formula 1 below: 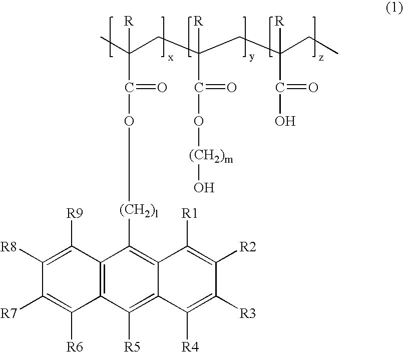
wherein R is hydrogen or methyl, R₁-R₉ are each independently hydrogen, C₁-C₆ linear or branched alkyl, hydroxy, alkoxyalkyl, methoxycarbonyl, carboxyl, or hydroxymethyl, 1 is 1 or 2, m is 2, 3, or 4, and x, y, and z are each independently from 0.05 to 0.95.

2. The organic anti-reflective coating polymer according to claim 1, wherein R is methyl, R₁-R₉ is hydrogen, 1 is 1, and m is 2 in Formula 1.

3. A method for preparing an organic anti-reflective coating polymer of Formula 1 below: 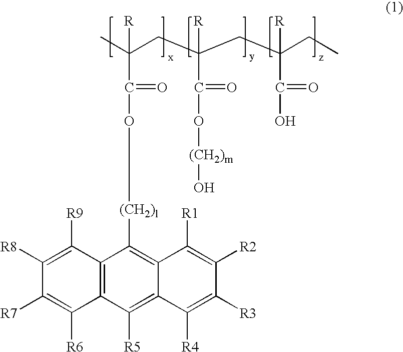
wherein R is hydrogen or methyl, R₁-R₉ are each independently hydrogen, C₁-C₆ linear or branched alkyl, hydroxy, alkoxyalkyl, methoxycarbonyl, carboxyl, or hydroxymethyl, 1 is 1 or 2, m is 2, 3, or 4, and x, y, and z are each independently from 0.05 to 0.95,
the method comprising the steps of:
dissolving an 9-anthracenealkyl acrylate monomer of Formula 2 below: 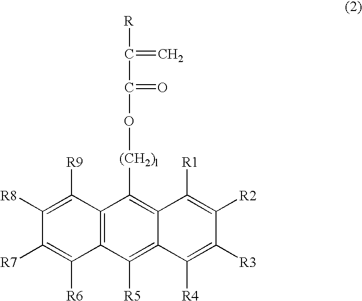
wherein R is hydrogen or methyl, R₁-R₉ are each independently hydrogen, C₁-C₆ linear or branched alkyl, hydroxy, alkoxyalkyl, methoxycarbonyl, carboxyl, or hydroxymethyl, and 1 is 1 or 2,
a hydroxyalkyl acrylate monomer of Formula 3 below: 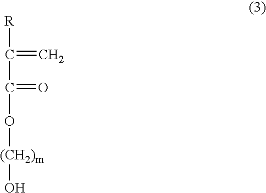
wherein R is hydrogen or methyl, and m is 2, 3, or 4, and
an acrylic acid monomer of Formula 4 below: 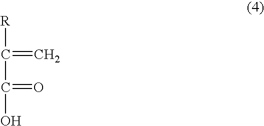
wherein R is hydrogen or methyl,
in an organic solvent; and
subjecting the mixture to copolymerization in the presence of a radical polymerization initiator at a temperature of 60° C. to 70° C. for 4 hours to 12 hours.

4. The method according to claim 3, wherein the organic solvent includes at least one solvent selected from the group consisting of propylene glycol methyl ether acetate (PGMEA), tetrahydrofuran (THF), cyclohexanone, dimethylformamide, dimethylsulfoxide, dioxane, methyl ethyl ketone, benzene, toluene, xylene, and mixtures thereof.

5. The method according to claim 3, wherein the polymerization initiator includes at least one initiator selected from the group consisting of 2,2-azobisisobutyronitrile (AIBN), benzoly peroxide, acetyl peroxide, lauryl peroxide, t-butyl acetate, t-butyl hydroperoxide, and di-t-butyl peroxide.

6. An organic anti-reflective coating composition, the composition comprising:
an organic anti-reflective coating polymer having a weight-average molecular weight of 2,000 to 30,000, represented by Formula 1 below: 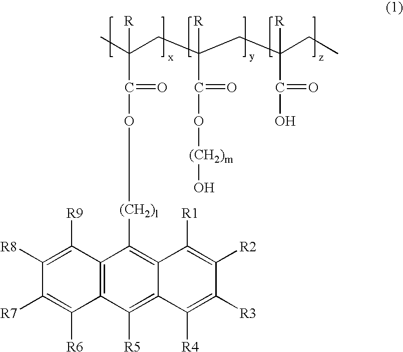
wherein R is hydrogen or methyl, R₁-R₉ are each independently hydrogen, C₁-C₆ linear or branched alkyl, hydroxy, alkoxyalkyl, methoxycarbonyl, carboxyl, or hydroxymethyl, 1 is 1 or 2, m is 2, 3, or 4, and x, y, and z are each independently from 0.05 to 0.95;
a crosslinking agent represented by Formula 5 below: 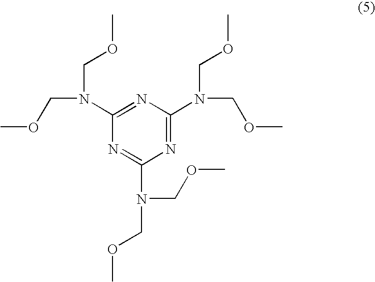
a thermal acid generator; and
an organic solvent.

7. The composition according to claim 6, wherein the thermal acid generator includes at least one of 2-hydroxycyclohexyl para-toluenesulfonate and triphenylsulfonium perfluoromethanesulfonate.

8. A method for forming a photoresist pattern, comprising the steps of:
applying the organic anti-reflective coating composition according to claim 6 on an ion implantation layer;
baking the resulting structure to form an organic anti-reflective coating;
applying a negative photoresist on the organic anti-reflective coating; and
exposing the negative photoresist to light, followed by developing to form a photoresist pattern.

9. The method according to claim 8, comprising conducting the baking at a temperature of 150° C. to 300° C. for 1 minute to 5 minutes.

10. The method according to claim 8, further comprising the sub-step of baking before or after the exposure.

11. The method according to claim 10, comprising conducting the baking is conducted at a temperature of 70° C. to 200° C.
